(19) United States
(12) Patent Application Publication
(10) Pub. No.: US 2017/0047914 A1
(43) Pub. Date: Feb. 16, 2017

(54) PULSE GENERATOR WITH SWITCHED CAPACITORS

(71) Applicant: International Business Machines Corporation, Armonk, NY (US)

(72) Inventors: Kohji Hosokawa, Ohtsu-shi (JP); Masatoshi Ishii, Ohmihachiman-shi (JP); Mark B. Ritter, Sherman, CT (US); Takeo Yasuda, Nara-shi (JP)

(21) Appl. No.: 14/824,382

(22) Filed: Aug. 12, 2015

(51) Int. Cl. H03K 4/50; H01L 49/02

(52) U.S. Cl. CPC H03K 4/50; H01L 28/40

(57) ABSTRACT

A pulse generator and a method of fabricating a pulse generator are described. The pulse generator includes an input node to receive an input voltage, a first capacitor, and a second capacitor. The first capacitor is positioned between the input node and the second capacitor. An output node outputs an output voltage with a pulse shape, and the pulse generator also includes at least one switch between the input node and the second capacitor. The at least one switch controls the pulse shape of the output voltage.

### BACKGROUND

The present invention relates to a pulse generator, and more specifically, to a pulse generator with switched capacitors.

A resistance and capacitance (RC) time constant may be used to implement a continuous delay period. An RC circuit may be part of an integrated circuit, for example, and may be part of a pulse generator with an adjustable pulse shape. The pulse delay and shape is adjustable through the period and signal waveform for capacitance charge or discharge. This adjustable range of the resistance and capacitance is limited by the silicon area where the resistance and capacitance are implemented.

### SUMMARY

Embodiments include a pulse generator and a method of fabricating a pulse generator. The pulse generator includes an input node to receive an input voltage, a first capacitor, and a second capacitor. The first capacitor is positioned between the input node and the second capacitor. An output node outputs an output voltage with a pulse shape, and the pulse generator also includes at least one switch between the input node and the second capacitor. The at least one switch controls the pulse shape of the output voltage.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 shows pulse generator circuit implemented according to embodiments;

FIG. 2 shows one embodiment of the pulse generator circuit shown in FIG. 1;

FIG. 3 shows the timing of the signal that controls the switching in the Rsc implementation shown in FIG. 2;

FIG. 4 shows another embodiment of the pulse generator circuit shown in FIG. 1;

FIG. 5 shows the timing of the signals that control the switching in the Rsc implementation shown in FIG. 4;

FIG. 6 is a pulse generator implemented with transistors according to an embodiment;

FIG. 7 illustrates an exemplary timing diagram associated with the pulse generator shown in FIG. 6;

FIGS. 8-13 illustrate exemplary pulse shapes at the output node achieved with a pulse generator according to embodiments, in which:

FIG. 8 illustrates a pulse shape with a rise time from voltage value VM to VH;

FIG. 9 illustrates a pulse shape with a rise time from voltage value VL to VM;

FIG. 10 illustrates a pulse shape with a fall time from voltage value VH to VM;

FIG. 11 illustrates a pulse shape with a fall time from voltage value VM to VL;

FIG. 12 shows exemplary pulse shapes according to embodiments; and

FIG. 13 illustrates a pulse with a fall time followed by a pulse with a rise time;

FIG. 14 is a pulse generator implemented with transistors according to another embodiment;

FIG. 15 illustrates an exemplary timing diagram associated with the pulse generator shown in FIG. 14;

FIG. 16 is an exemplary pulse waveform generated by a pulse generator according to embodiments;

FIG. 17 shows an exemplary variable capacitor for use in a pulse waveform generator according to embodiments;

FIG. 18 is a pulse generator implemented with transistors and variable capacitors according to another embodiment; and

FIG. 19 is a block diagram of a pulse generator system according to embodiments.

### DETAILED DESCRIPTION

As noted above, an RC circuit may be used to produce a pulse generator with an adjustable pulse shape, but the range of resistance and capacitor values (and thus the range of adjustability of the shape) is limited by the silicon area available for implementation of the resistance and capacitance. The capacitance requires a larger area for a larger value, and the resistance requires a larger length and a certain width for a larger value. For example, an RC time constant on the order of several tenths of microseconds requires several mega ohm (Me) order resistance, even with a 10 picofarad (pF) capacitance. Embodiments of the method and system detailed herein relate to a pulse generator with switches and capacitors that facilitate obtaining a larger time constant for a given capacitor size.

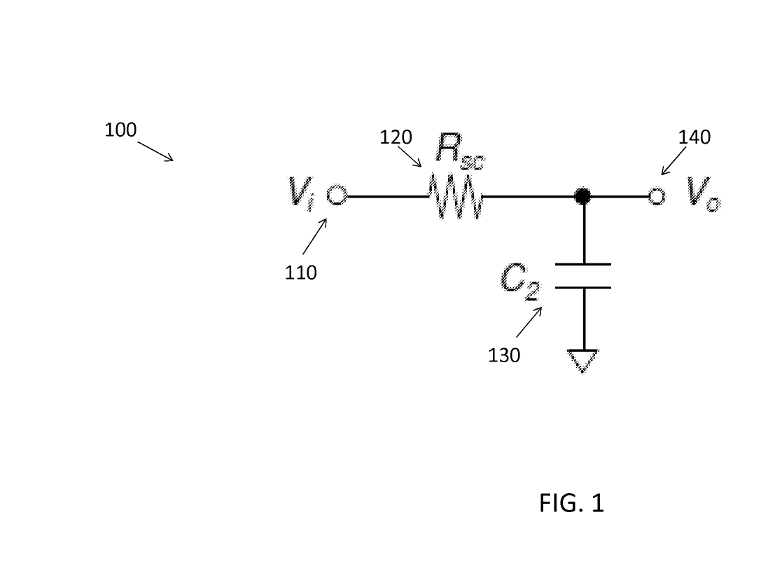

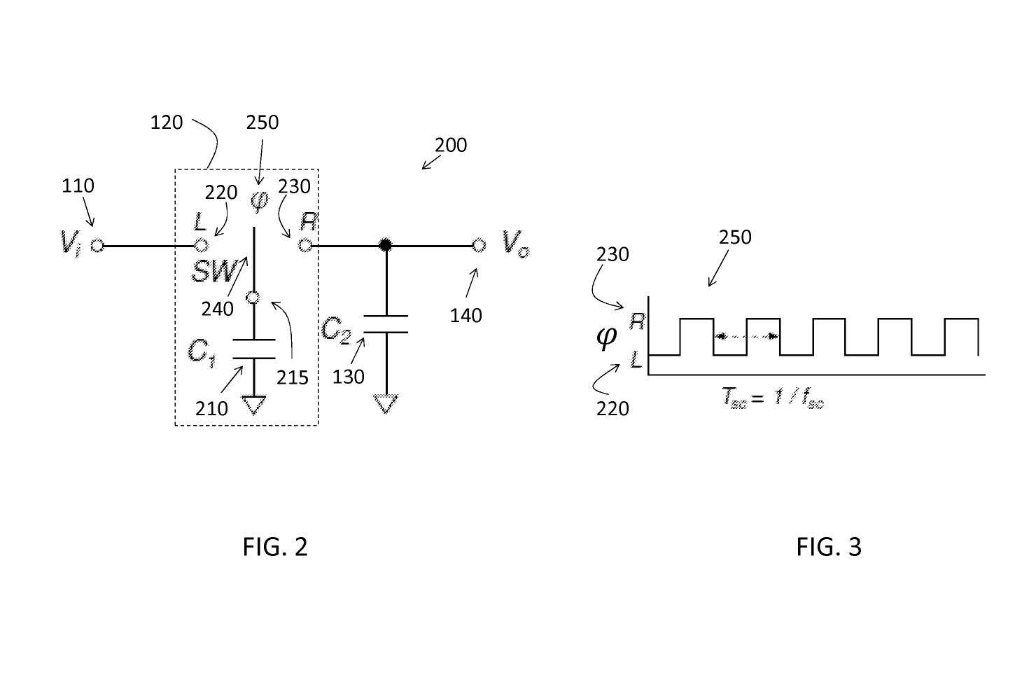

FIG. 1 shows pulse generator circuit 100 implemented according to embodiments detailed herein. A constant input voltage is applied at node Vᵢ 110. The pulse generated at node Vₒ 140 is shaped by R_{sc} 120 and C₂ 130. The rise time and fall time delay and shape of the pulse at Vₒ 140 is adjustable based on R_{sc} 120 and C₂ 130. Unlike a conventional RC circuit, R_{sc} 120 is not simply a resistance but a representation of a charge transfer portion detailed further below. FIGS. 2 and 3 illustrate two different embodiments for R_{sc} 120.

FIG. 2 shows one embodiment of the pulse generator circuit 200 shown in FIG. 1. R_{sc} 120 is implemented by a capacitor C₁ 210 whose upper node 215 (the node not connected to ground) is connected to the node Vᵢ 110 (L side node 220) or the node Vₒ 140 (R side node 230) by the switch SW 240 alternately at a cycle time T_{sc}, which is given by:

$${T}_{sc} = \frac{1}{{f}_{sc}} \qquad [ EQ . 1 ]$$

The switching frequency is f_{sc}. The switch SW 240 is controlled by a signal φ 250. Based on the switching, the charge at the node Vᵢ 110 is transferred to the node Vₒ 140 over time. FIG. 3 shows the timing of the signal φ 250 that controls the switching in the R_{sc} 120 implementation shown in FIG. 2.

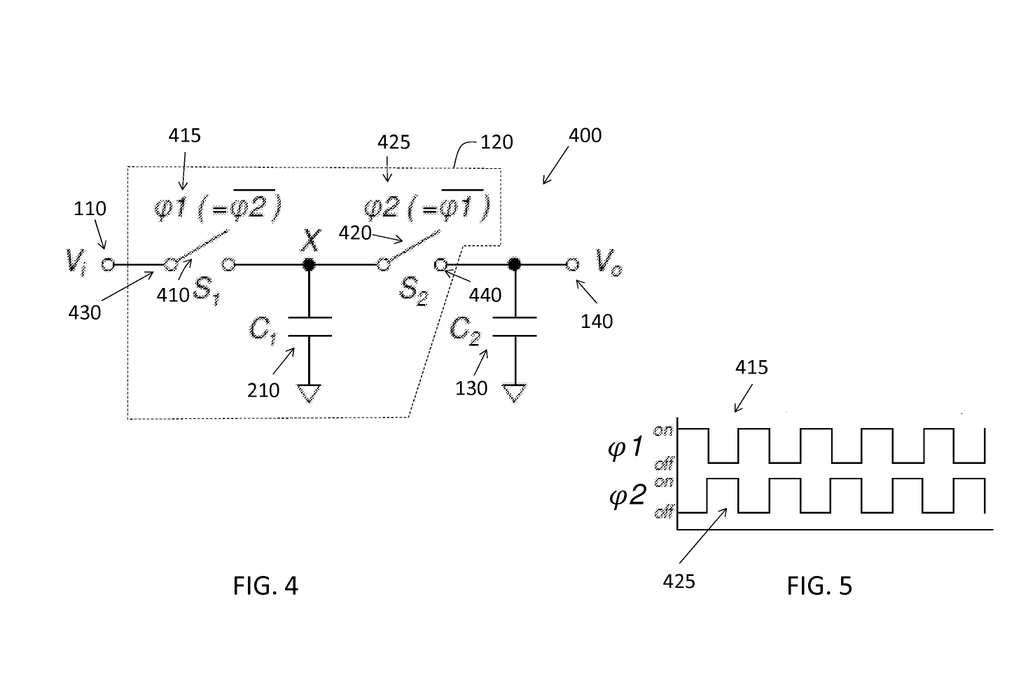

FIG. 4 shows another embodiment of the pulse generator circuit 400 shown in FIG. 1. As FIG. 4 indicates, the implementation of R_{sc}120 according to the current embodiment includes two switches S₁ 410, S₂ 420 and capacitor C₁ 210. The capacitor C₁ 210 (specifically, the upper node indicated by X) is either isolated from or connected to each of node Vᵢ 110 and node Vₒ 140 based on the position of switches S₁ 410 and S₂ 420, respectively. The switches S₁ 410 and S₂ 420 are “on” alternately based, respectively, on signals φ1 415 and φ2 425. That is, the “on” period of signals φ1 415 and φ2 425 are ensured not to overlap. In addition, the “on” period for each of the signals φ1 415 and φ2 425 is selected to be long enough so that the voltage potentials at nodes 430 and 440 are equalized based on charge sharing within the “on” period. The switching cycle periods (“on” and “off” period of each switch 410, 420) may be the same (T_{sc}) as shown in FIG. 3 for the embodiment of the pulse generator circuit 200 shown in FIG. 2. FIG. 5 shows the timing of the signals φ1 415 and φ2 425 that control the switching in the Rsc 120 implementation shown in FIG. 4. As noted above and shown in FIG. 5, the switching cycle period of switch S₁ 410 according to signal φ1 415 is the opposite of the switching cycle period of switch S₂ 420 according to signal φ2 425.

If C₂ is much larger than C₁, the charge at the node Vᵢ 110 is transferred to the nodeVₒ 140 gradually. The amount of change transferred for one switching cycle (S₁ 410 on and S₂ 420 off followed by S₁ 410 off and S₂ 420 on) is given by:

$${Q}_{1} - {Q}_{1}^{′} = {Q}_{2}^{′} - {Q}_{2} = \frac{{C}_{1} {C}_{2} ( {V}_{i} - {V}_{0} )}{{C}_{1} + {C}_{2}} \qquad [ EQ . 2 ]$$

The charge of capacitances C₁ 210 and C₂ 130 in stable state after switch S₁ 410 is on and S₂ 420 is off is Q₁ and Q₂, respectively. The charge of capacitances C₁ 210 and C₂ 130 in stable state after switch S₁ 410 is off and S₂ 420 is on is Q₁′ and Q₂′, respectively. Given a switching frequency of the signals φ1 415 and φ2 425 of f_{sc}, charge transfer occurs f_{sc} times every 1 second. As a result, current I_{sc} from node Vᵢ 110 to node Vₒ 140 is given by:

$${I}_{sc} = \frac{{f}_{sc} {C}_{1} {C}_{2} ( {V}_{i} + {V}_{0} )}{{C}_{1} + {C}_{2}} \qquad [ EQ . 3 ]$$

From EQ. 3, the equivalent resistance R_{sc} 120 between node Vᵢ 110 and node Vₒ 140 may be determined as:

$${R}_{SC} = \frac{{V}_{i} - {V}_{0}}{{I}_{SC}} = \frac{{C}_{1} + {C}_{2}}{{f}_{SC} {C}_{1} {C}_{2}} \qquad [ EQ . 4 ]$$

Based on EQ. 4, the pulse generator circuit 100 shown in FIG. 1 has a time constant given by:

$${R}_{SC} {C}_{2} = \frac{{C}_{1} + {C}_{2}}{{f}_{SC} {C}_{1}} = \frac{1 + \frac{{C}_{2}}{{C}_{1}}}{{f}_{sc}} \qquad [ EQ . 5 ]$$

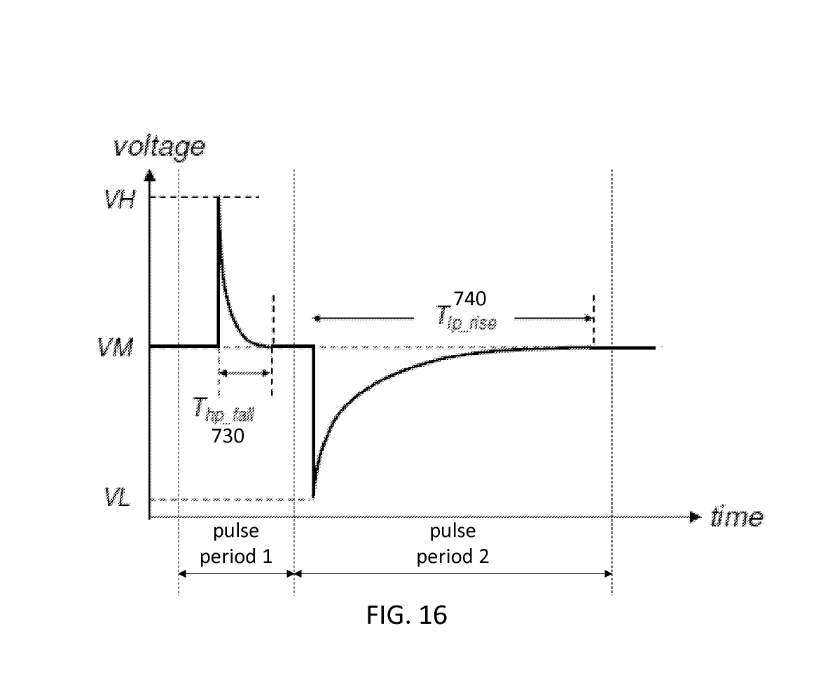

As EQ. 5 indicates, for a given value of C₂, the time constant (R_{sc}C₂) may be made larger by decreasing the value of C₁ or f_{sc}. Thus, the pulse generator circuit 100 according to the embodiments shown facilitates an increase in the time constant without a large capacitance or resistance. In fact, as further discussed with reference to FIG. 16 below, any one or more of C₁, f_{sc}, and C₂ may be controlled to control the pulse shape.

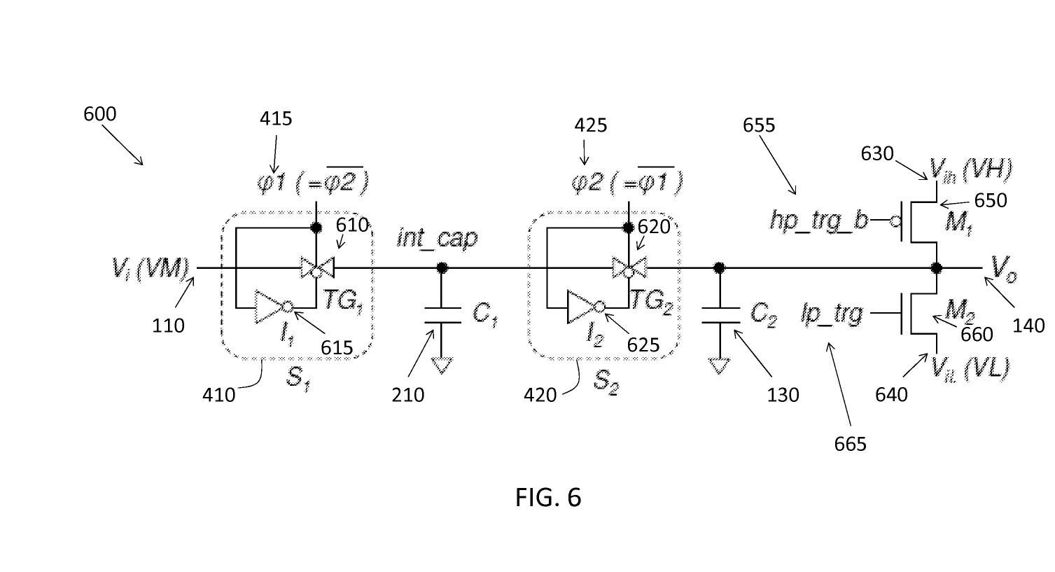

FIG. 6 is a pulse generator 600 implemented with transistors according to an embodiment. The switch S₁ 410 is implemented with transfer gate TG₁ 610 and inverter I₁ 615, and the switch S₂ 420 is implemented with transfer gate TG₂ 620 and inverter I₂ 625. The capacitor C₁ 210 (specifically, the upper node indicated by int_cap) is isolated from or connected to node Vᵢ 110 and node Vₒ 140 with switches S₁ 410 and S₂ 420, respectively. The node Vᵢ 110 is set to voltage potential VM. Output node Vₒ 140 is connected to nodes Vᵢₕ 630 and Vᵢₗ 640 through metal-oxide-semiconductor field effect transistors (MOSFETs) M₁ 650 and M₂ 660, respectively. The M₁ 650 and M₂ 660 portion can be thought of as an initialization portion of the pulse generator 600. The nodes Vᵢₕ 630 and Vᵢₗ 640 are set to voltage potentials VH and VL, respectively. In the exemplary pulse generator 600 shown in FIG. 6, VH may be assumed to be higher than VM, and VL may be assumed to be lower than VM. These voltage potentials (VH and VL) are used to initialize node Vₒ 140. The signals hp_trg_b 655 and lp_trg 665 are used to set the initial value at the output node Vₒ 140 to either VH or VL. In either case, based on the switches S₁ 410 and S₂ 420 turning on and off alternately based on switch signals φ1 415 and φ2 425 (one switch is on while the other is off), the voltage potential of node Vₒ 140 approaches that of node Vᵢ 110 (VM) gradually.

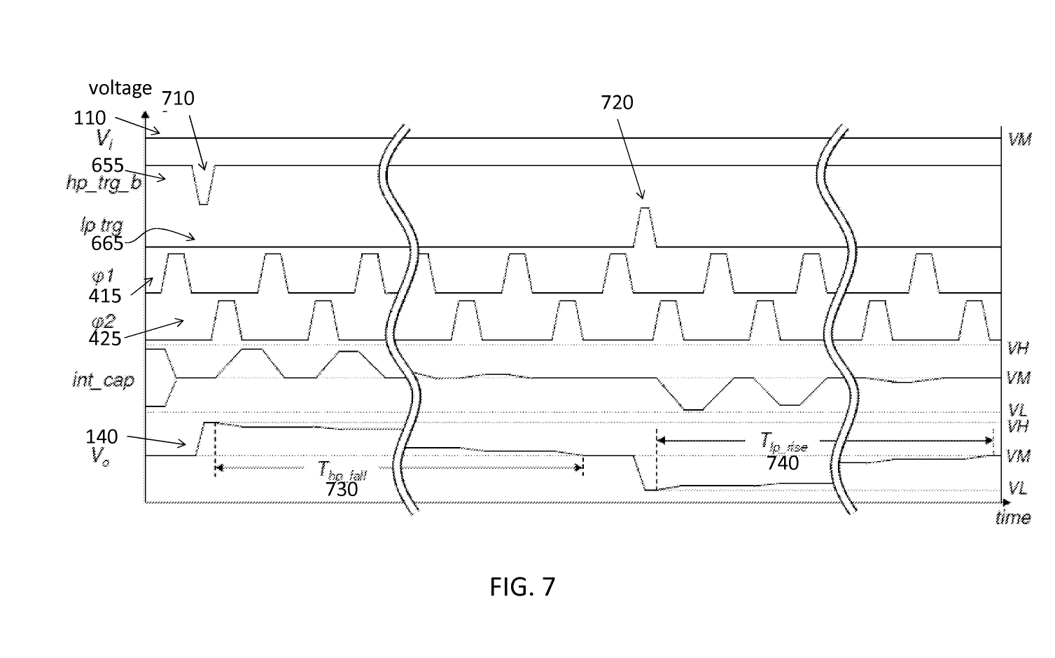

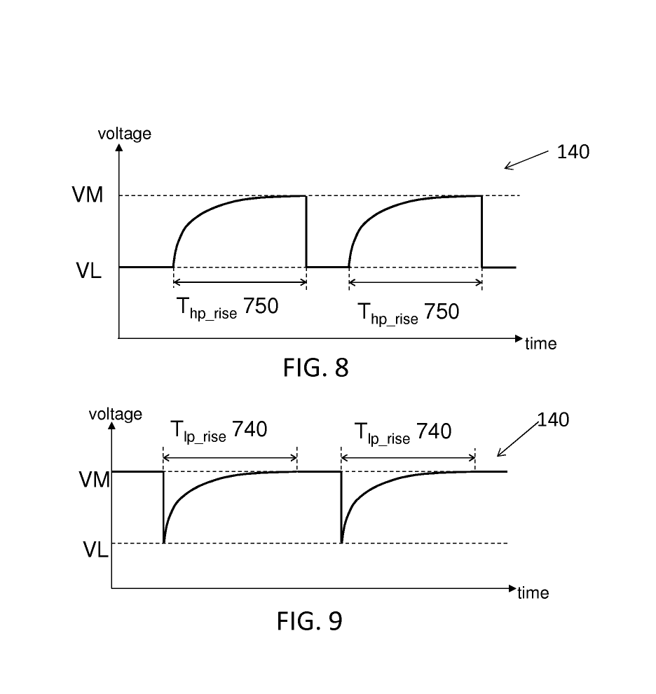

FIG. 7 illustrates an exemplary timing diagram associated with the pulse generator 600 shown in FIG. 6. The voltage at node Vᵢ 110 is kept constant at VM. Based on the trigger 710 from signal hp_trg_b 655 associated with MOSFET M₁ 650, the voltage at the output node Vₒ 140 is initially set to VH. According to switches S₁ 410 and S₂ 420, which turn on and off in opposite phase over the high pulse fall time Tₕₚ_{_}_{fall} 730, the voltage at the output node Vₒ 140 approaches VM. Then, based on a trigger 720 from signal lp_trg 665 associated with MOSFET M₂ 660, the voltage at the output node Vₒ 140 is set to VL. According to switches S₁ 410 and S₂ 420 which turn on and off in opposite phase over the low pulse rise time Tᵢₚ_{_}ᵣᵢₛₑ 740, the voltage at the output node Vₒ 140 approaches VM. This fall and rise of the voltage at the output node Vₒ 140 over Tₕₚ_{_}_{fall} 730 and Tₗₚ_{_}ᵣᵢₛₑ 740 represent pulse shapes achieved with the switches S₁ 410 and S₂ 420. Other exemplary pulse shapes are illustrated in FIGS. 8-13.

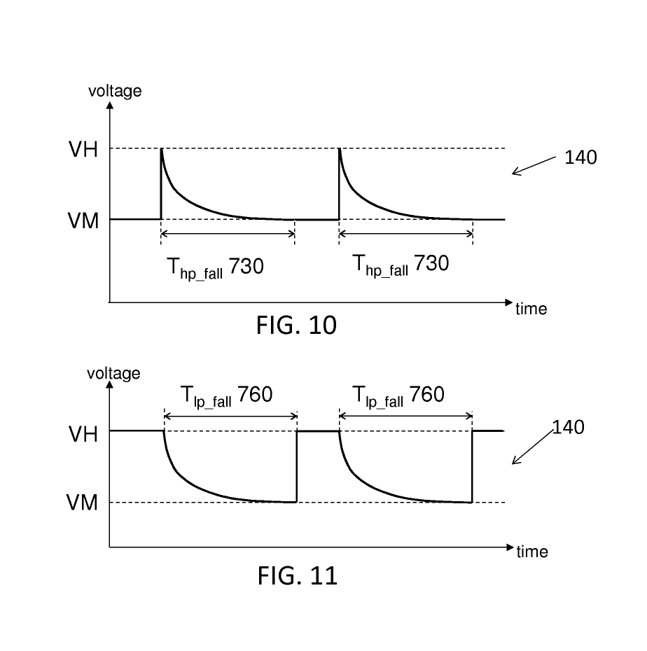

FIGS. 8-13 illustrate exemplary pulse shapes at the output node Vₒ 140 achieved with a pulse generator according to embodiments. FIG. 8 shows an exemplary pulse shape with a high pulse rise time Tₕₚ_{_}ᵣᵢₛₑ 750 from VL (the voltage at the node Vᵢₗ 640 in the embodiment shown in FIG. 6) to VM (the voltage at the node Vᵢ 110 in the embodiment shown in FIG. 6). FIG. 9 shows an exemplary pulse shape with a low pulse rise time Tₗₚ_{_}ᵣᵢₛₑ 740 from VL (the voltage at the node Vᵢₗ 640 in the embodiment shown in FIG. 6) to VM (the voltage at the node Vᵢ 110 in the embodiment shown in FIG. 6). FIG. 10 shows an exemplary pulse shape with a high pulse fall time Tₕₚ_{_}_{fall} 730 from VH (the voltage at the node Vᵢₕ 630 in the embodiment shown in FIG. 6) to VM (the voltage at the node Vᵢ 110 in the embodiment shown in FIG. 6). FIG. 11 shows an exemplary pulse shape with a low pulse fall time Tₗₚ_{_}_{fall} 760 from VH (the voltage at the node Vᵢₕ 630 in the embodiment shown in FIG. 6) to VM (the voltage at the node Vᵢ 110 in the embodiment shown in FIG. 6).

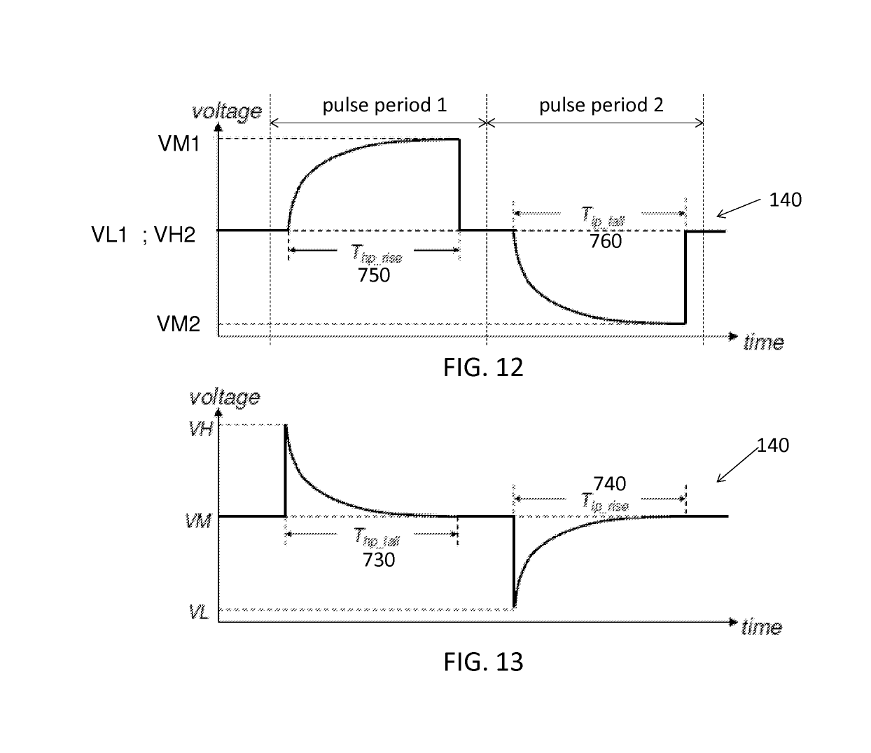

FIG. 12 shows exemplary pulse shapes according to embodiments. FIG. 12 illustrates the fact that the values of the voltages (e.g., voltages VH, VM, VL shown in FIG. 6) may differ from one pulse to the next. In pulse period 1 shown in FIG. 12, the pulse shape has a high pulse rise time Tₕₚ_{_}ᵣᵢₛₑ 750 from VL1 to VM1 and, in pulse period 2, the pulse shape has a low pulse fall time Tᵢₚ_{_}_{fall} 760 from VH2 to VM2. As noted above, according to the current embodiment, the values of VH, VM, and VL shown in FIG. 6 are modified depending on the time phase. During pulse period 1, the voltage levels VL1 and VM1 correspond to the levels VL and VM in FIG. 8, respectively. During pulse period 2, the voltage levels VH2 and VM2 correspond to the levels VH and VM in FIG. 11, respectively.

FIG. 13 shows an exemplary pulse shape with a high pulse fall time Tₕₚ_{_}_{fall} 730 from VH to VM and a pulse shape with a low pulse rise time Tₗₚ_{_}ᵣᵢₛₑ 740 from VL to VM. All of the pulse shapes shown for the node Vₒ 140 are achieved by presetting the voltage at the node Vₒ 140 to the initial voltage which is supplied at node Vᵢₕ 630 or Vᵢₗ 640 based on the MOSFETS M₁ 650 or M₂ 660 and then alternately operating the switches S₁ 410 and S₂ 420 to raise or lower the voltage gradually towards the voltage of node Vᵢ 110 in the embodiment shown in FIG. 6. While the examples discussed thus far relate to implementations with two switches, three or more switches may be used to shape the pulses at the node Vₒ 140, as well.

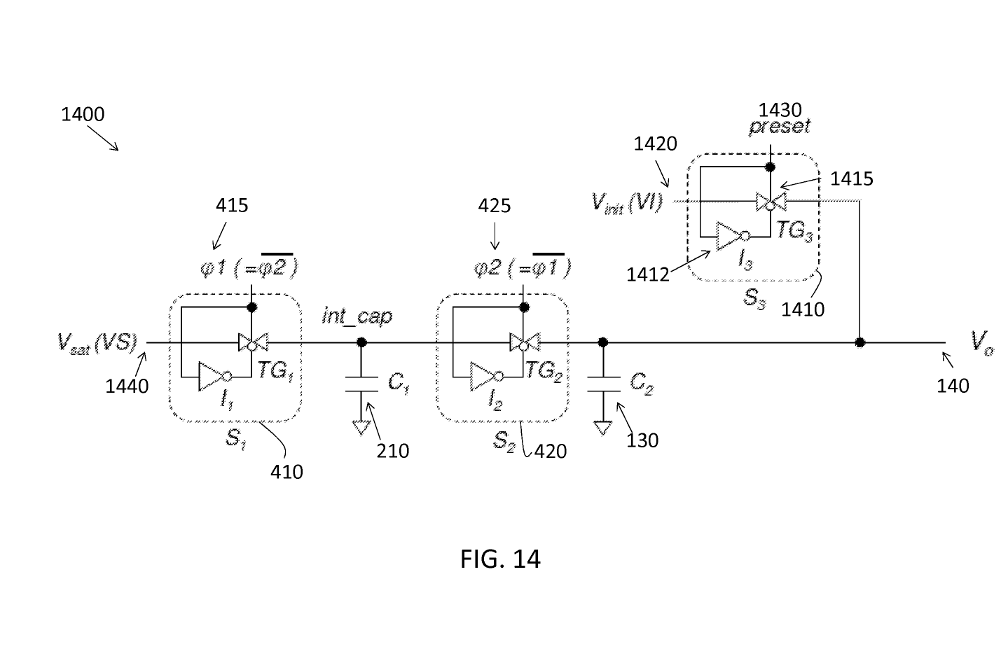

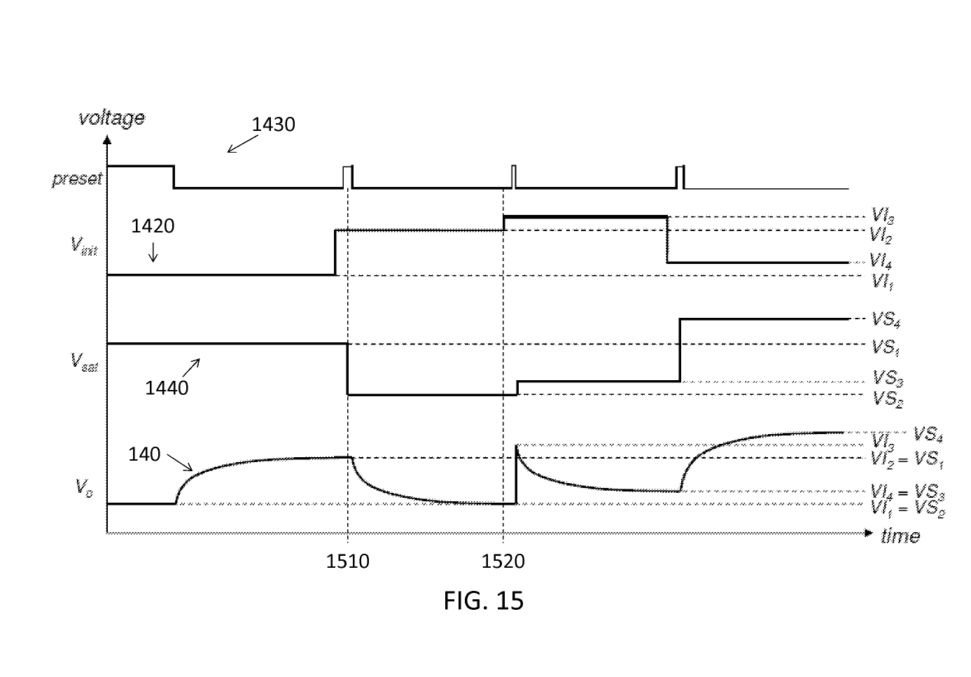

FIG. 14 is a pulse generator 1400 implemented with transistors according to another embodiment. As FIG. 14 shows, the embodiment includes three switches. In addition to switches S₁ 410 and S₂ 420, a third switch S₃ 1410 is included and is arranged to couple the node Vₒ 140 to an initial voltage node Vᵢₙᵢₜ 1420. In comparison to the embodiment shown in FIG. 6, the third switch S₃ 1410 may be regarded as a combination of M₁ 650 or M₂ 660, the preset signal 1430 may be regarded as a combination of signals hp_trg_b 655 and lp_trg 665, and the voltage VI at node Vᵢₙᵢₜ 1420 may be regarded as a combination of voltages VH and VL. That is, the transfer gate TG₃ 1415 couples an n-channel MOSFET and a p-channel MOSFET (rather than having them separated as M₁ 650 or M₂ 660 as in the embodiment of FIG. 6). As such, the n-channel device can preset the voltage at the node Vₒ 140 to VI even when VI is lower than the saturation voltage VS at the node Vₛₐₜ 1440. On the contrary, the p-channel device can preset the voltage at the node Vₒ 140 to VI even when VI is higher than the saturation voltage VS at the node Vₛₐₜ 1440. The value of VI at the node Vᵢₙᵢₜ 1420 determines the preset voltage at the node Vₒ 140, while the preset signal 1430 determines the preset timing. The switches S₁ 410 and S₂ 420, which are controlled by the (alternate) signals φ1 415 and φ2 425, respectively, determine the pulse shape (rise or fall time of the pulse) at the node Vₒ 140. This is illustrated in FIG. 15.

FIG. 15 illustrates an exemplary timing diagram associated with the pulse generator 1400 shown in FIG. 14. An important point illustrated by FIG. 15 is that the initialization voltage VI (at the node Vᵢₙᵢₜ 1420) and the saturation voltage VS (at the node Vₛₐₜ 1440) need not be constant voltages. In the example shown in FIG. 15, each of the voltages VI and VS has four different values. In alternate embodiments, any number of values is possible. In contrast, in the exemplary timing diagram of FIG. 7, which relates to the embodiment shown in FIG. 6, voltages VM, VL, and VH each has a single value. As shown in FIG. 15, the preset signal 1430 sets the voltage at the node Vₒ 140 to VI which is the voltage at the node Vᵢₙᵢₜ 1420. Then, based on the switches S₁ 410 and S₂ 420, the voltage at the node Vₒ 140 rises or falls to VS which is the voltage at the node Vₛₐₜ 1440. For example, when the preset signal 1430 is applied at a time labeled 1510, voltage at the node Vᵢₙᵢₜ 1420 is at VI₂ and voltage at the node Vₛₐₜ 1440 is VS₂. Thus, voltage at the node Vₒ 140 is preset to VI₂ but, based on switches S₁ 410 and S₂ 420, the voltage at the node Vₒ 140 approaches VS₂ (by falling in this example) until a time labeled 1520. Again, unlike the embodiment discussed with reference to FIGS. 6 and 7 (in which VH was always greater than VM and VL was always less than VM), the voltage at the node Vᵢₙᵢₜ 1420 is not always greater than or always less than the voltage at the node Vₛₐₜ 1440. This difference results in the pulse shapes shown in the exemplary timing diagram of FIG. 15.

FIG. 16 is an exemplary pulse waveform generated by a pulse generator according to embodiments. While the labels (e.g., VH, VM, VL) relate to the description of the embodiment shown in FIG. 6, the pulse waveform shown in FIG. 16 may be achieved by other embodiments detailed herein, as well. FIG. 16 illustrates a pulse (at the node Vₒ 140) with a high pulse fall time Tₕₚ_{_}_{fall} 730 from VH to VM and a pulse with a low pulse rise time Tₗₚ_{_}ᵣᵢₛₑ 740 from VL to VM. As FIG. 16 shows, the high pulse fall time Tₕₚ_{_}_{fall} 730 and the low pulse rise time Tᵢₚ_{_}ᵣᵢₛₑ 740 have different values. In the example shown in FIG. 16, the rise time Tᵢₚ_{_}ᵣᵢₛₑ 740 is longer than the fall time Tₕₚ_{_}_{fall} 730 (pulse period 2 is longer than pulse period 1). As noted above, the switches S₁ 410 and S₂ 420 control the pulse shape. That is, one way to differentiate Tₕₚ_{_}_{fall} 730 and Tᵢₚ_{_}ᵣᵢₛₑ 740 is changing the frequency of switching (frequency with which the signals φ1 415 and φ425 are provided). This is consistent with EQ. 5 above, which shows that, as f_{sc} increases, the time constant (R_{SC}C₂) decreases (pulse is faster). The frequency of signals φ1 415 and φ2 425 (which may have the same frequency) determines the speed of charge transfer. For example, when the frequency of signals φ1 415 and φ2 425 is low (switching is slow), then the charge transfer is slow and the pulse shape is such that rise time or fall time is large. Thus, the difference of the high pulse fall time Tₕₚ_{_}_{fall} 730 and the low pulse rise time Tᵢₚ_{_}ᵣᵢₛₑ 740 shown in FIG. 16 may be a result of modifying the switching frequency of φ1 415 and φ2 425 to be higher at pulse period 1 and lower at pulse period 2, for example.

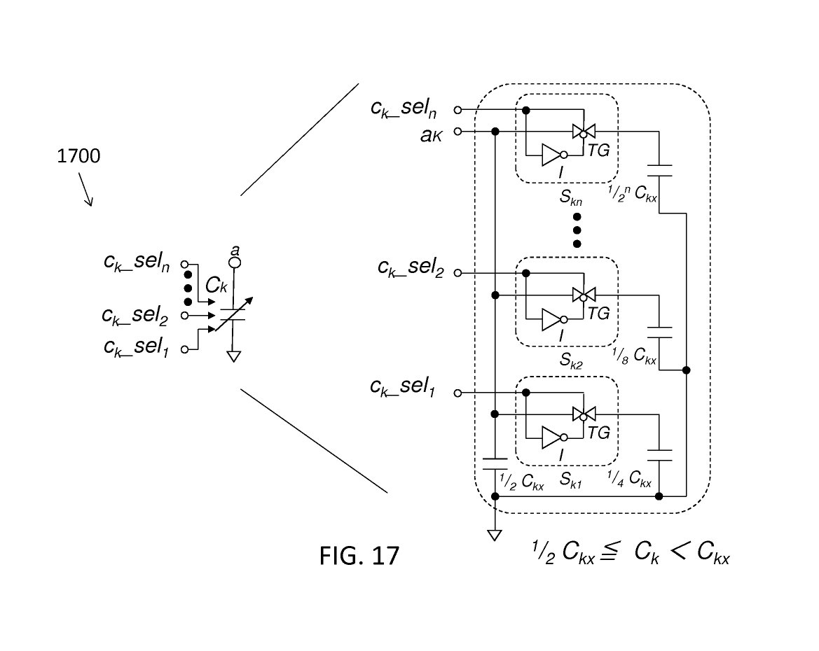

Another parameter used to modify the rise or fall time of a pulse (voltage pulse at the node Vₒ 140) is capacitance ratio of C₁ and C₂. This is also consistent with EQ. 5, which shows that, as C₂/C₁ increases, time constant (R_{SC}C₂) increases (pulse is slower). Stated another way, a smaller C₁/C₂ (C₁ is smaller or C₂ is larger) results in a larger rise or fall time (increase in time constant). Thus, the difference in the high pulse fall time Tₕₚ_{_}_{fall} 730 and the low pulse rise time Tᵢₚ_{_}ᵣᵢₛₑ 740 shown in FIG. 16 may also be a result of changing the size ratio of the two capacitances C₁/C₂ to be larger at pulse period 1 and smaller at pulse period 2. This change may be achieved by implementing one or both of the capacitors C₁ and C₂ as variable and controllable. FIG. 17 shows an exemplary variable capacitor 1700 (detailed on the right) for use in a pulse generator 100 according to the various embodiments discussed herein. Because both of the capacitors C₁ 210 and C₂ 130 may be implemented as a variable capacitor (each capacitor is implemented by the circuit shown in FIG. 17), the subscript k is used to denote capacitor number such that k could be 1 or 2 (C₁ 210 or C₂ 130). The value of Cₖₓ may be different for each k. As FIG. 17 indicates, for each capacitor (each value of k), any (or all) of the switches cₖ_{_}sel₀ to cₖ_{_}selₙ may be open or closed.

When all the switches (cₖ_{_}sel₀ to cₖ_{_}selₙ) are open, the value of capacitance Cₖ is ½Cₖₓ. When all the switches are closed, the value of capacitance Cₖ approaches Cₖₓ. That is, when all the switches are closed, the value of the capacitance Cₖ is given by:

((½+¼+⅛+ . . . +(½)ⁿ)Cₖₓ) EQ. [6]

Accordingly, Cₖ (again, where k is either 1 or 2) may have a corresponding capacitance value ranging from:

½C_{kc}≦Cₖ<Cₖₓ [EQ. 7]

Further, Cₗₓ and C₂ₓ need not be the same value such that the range of capacitance values (½Cₖₓ≦Cₖ<Cₖₓ) that C₁ 210 is controlled to have and the range of capacitance values that C₂ 130 is controlled to have are different. As noted above and indicated by EQ. 5, the value of interest in shaping the output voltage pulse (at node V₀ 140) is the ratio of the capacitance values of C₂ 130 and C₁ 210.

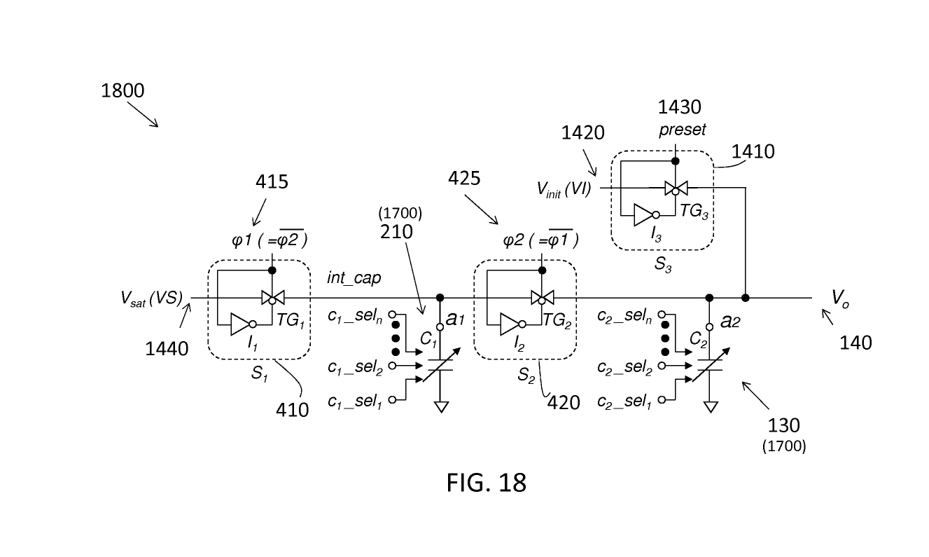

FIG. 18 is a pulse generator 1800 implemented with transistors and variable capacitors according to another embodiment. FIG. 18 essentially shows the pulse generator 1400 of FIG. 14 with the capacitors C₁ 210 and C₂ 130 implemented as variable capacitors 1700. The components of the pulse generator 1800 that are the same a those of the pulse generator 1400, shown in FIG. 14, are not discussed again. As FIG. 18 shows, the capacitors C₁ 210 and C₂ 130 are both replaced with variable capacitors 1700. In the case of C₁ 210, when k=1, a₁ corresponds with int_cap. In the case of C₂ 130, when k=2, a₂ corresponds with node V₀ 140.

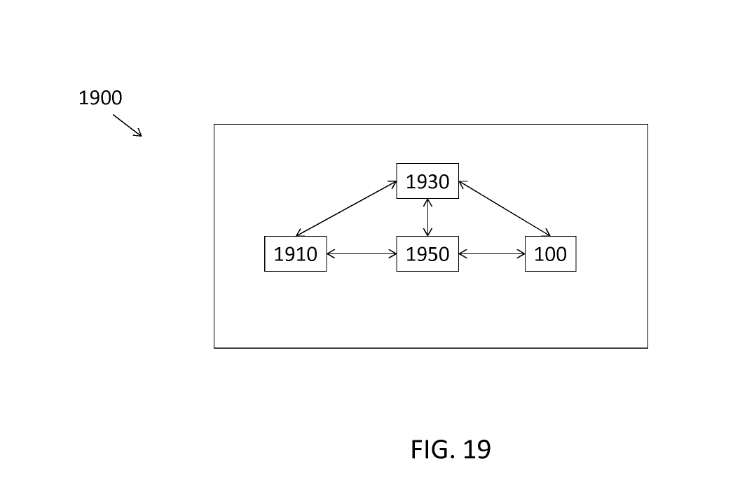

FIG. 19 is a block diagram of a pulse generator system 1900 according to embodiments. The pulse generator system 1900 includes any of the embodiments (200, 400, 600, 1400, 1800) of the pulse generator 100 discussed above. In addition, the pulse generator system 1900 includes an interface 1910 to receive inputs such as specifications of the desired pulse shape and other characteristics from a user or another system. The pulse generator system 1900 also includes one or more processors 1950 and one or more memory devices 1930 to store instructions for the processor 1950 and parameter values as needed. Other known components (e.g., voltage sources) that may be part of the pulse generator system 1900 or may be inputs are not detailed herein. The selection among cₖ_{_}sel₀ to cₖ_{_}selₙ (for both k=1 and k=2), as well as control of the signals φ 250, φ 1 415, and φ2 425, and the preset signal 1430, discussed above, may be achieved by the processor 1950 acting according to a user input or input from another system via the interface 1910. The processor 1950 may instead determine the selection among cₖ_{_}sel₀ to cₖ_{_}selₙ, as well as (timing) control of the signals φ 250, φ1 415, and φ2 425, and the preset signal 1430 based on an input of a desired pulse shape.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A pulse generator, comprising:
an input node configured to receive a constant input voltage;
a first capacitor;
a second capacitor, the first capacitor positioned between the input node and the second capacitor;
an output node configured to output an output voltage with a pulse shape; and
at least one switch between the input node and the second capacitor, the at least one switch controlling the pulse shape of the output voltage.

2. (canceled)

3. The pulse generator according to claim 1, wherein the at least one switch is one switch coupled to a first capacitor node of the first capacitor, the one switch configured to alternately connect the first capacitor node to the input node and a second capacitor node of the second capacitor that is coupled to the output node.

4. The pulse generator according to claim 1, wherein the at least one switch is a first switch and a second switch.

5. The pulse generator according to claim 4, wherein the first switch connects the first capacitor to the input node in the first switch on position, the second switch connects the first capacitor to the second capacitor coupled to the output node in the second switch on position, and the first switch is in the first switch on position only when the second switch is not in the second switch on position.

6. The pulse generator according to claim 1, wherein the at least one switch is implemented with a transfer gate and an inverter.

7. The pulse generator according to claim 6, further comprising a first metal-oxide-semiconductor field effect transistor (MOSFET) and a second MOSFET.

8. The pulse generator according to claim 7, wherein an initial value of the output voltage is set based on either the first MOSFET or the second MOSFET.

9. The pulse generator according to claim 7, wherein the first MOSFET and the second MOSFET are controlled by respective MOSFET signals.

10. The pulse generator according to claim 6, further comprising an initialization switch additional to the at least one switch controlling the pulse shape of the output voltage.

11. The pulse generator according to claim 10, wherein an initial value of the output voltage is set based on the initialization switch.

12. The pulse generator according to claim 1, wherein the at least one switch is operated by a respective control signal.

13. The pulse generator according to claim 1, wherein at least one of the first capacitor and the second capacitor is a variable capacitor, and a ratio of the first capacitor and the second capacitor additionally controls the pulse shape of the output voltage.

14-20. (canceled)
